(19) United States
(12) Patent Application Publication
(10) Pub. No.: US 2026/0244281 A1
(43) Pub. Date: Aug. 20, 2026

(54) KEYBOARD CIRCUIT OF LIGHT EMITTING ANTI-GHOSTING KEYBOARD

(71) Applicant: SUNREX TECHNOLOGY CORP., Taichung City (TW)

(72) Inventors: Pei-Sin LIN, Taichung City (TW); Chih-Hsien Yao, Taichung City (TW)

(73) Assignee: SUNREX TECHNOLOGY CORP., Taichung City (TW)

(21) Appl. No.: 19/291,284

(22) Filed: Aug. 5, 2025

(30) Foreign Application Priority Data
Feb. 18, 2025 (TW) 114105948

(51) Int. Cl. G06F 3/023; H03M 11/00

(52) U.S. Cl. CPC G06F 3/023; H03M 11/003

(57) ABSTRACT

A keyboard circuit of a light-emitting anti-ghosting keyboard includes a switch unit and a processing unit. The switch unit includes a plurality of first driving lines, a plurality of second driving lines, a plurality of sensing lines, and a plurality of switch modules. Each of the switch modules is electrically connected to one of the first driving lines, one of the second driving lines, and one of the sensing lines, and includes a switch, a current-limiting resistor, and a light-emitting diode. The processing unit includes a first driving module connected to the first driving lines, a second driving module connected to the second driving lines, and a sensing module electrically connected to the second driving module. The sensing module includes a plurality of sensing pins that are connected respectively to the sensing lines, and is configured to measure an analog value of voltage at each of the sensing pins.

### CROSS-REFERENCE TO RELATED APPLICATION

This application claims priority to Taiwanese Invention Patent Application No. 114105948, filed on February 18, 2025, the entire disclosure of which is incorporated by reference herein.

### FIELD

The disclosure relates to a keyboard circuit, and more particularly to a keyboard circuit of a light-emitting anti-ghosting keyboard.

### BACKGROUND

U.S. Patent No. US 8,754,790 B2 discloses a conventional keyboard with ghost key suppression that includes a switch module, a comparator, an exchange unit and a processing unit. The switch module includes a plurality of driving lines for receiving respectively a plurality of driving signals, a plurality of sensing lines, a plurality of switches and a plurality of resistors. The comparator includes a first input end, a second input end for receiving a reference signal, and an output end, and is configured for comparing a signal received at the first input end with the reference signal for generating and outputting a comparison signal. The exchange unit is controlled by a control input to make and break electrical connection between each of the sensing lines and the first input end of the comparator. The processing module is configured to set at least one of the driving signals, the reference signal and the control input such that the comparison signal is able to indicate whether at least one of the switches is in a conducting state, whether at least one switch in a group of the switches is in a conducting state, or whether a single one of the switches is in a conducting state, in order to prevent an occurrence of “ghosting”.

Over time, people have started to desire adding a lighting function to keyboards to facilitate use in low-light environments. However, installing a backlight module on an underside of a conventional keyboard may significantly increase an overall thickness of the conventional keyboard.

### SUMMARY

Therefore, an object of the disclosure is to provide a keyboard circuit of a light-emitting anti-ghosting keyboard that can alleviate at least one of the drawbacks of the prior art.

According to the disclosure, the keyboard circuit includes a switch unit and a processing unit. The switch unit includes a plurality of first driving lines, a plurality of second driving lines, a plurality of sensing lines, and a plurality of switch modules. Each of the switch modules is electrically connected to one of the first driving lines, one of the second driving lines, and one of the sensing lines. Each of the switch modules includes a switch, a current-limiting resistor and a light-emitting diode (LED). The switch has a first end and a second end. The first end of the switch is electrically connected to the one of the sensing lines. The current-limiting resistor has a first end electrically connected to the second end of the switch, and a second end electrically connected to the one of the first driving lines. The LED has an anode electrically connected to the second end of the switch and the first end of the current-limiting resistor, and a cathode electrically connected to the one of the second driving lines. The processing unit includes a first driving module, a second driving module, and a sensing module. The first driving module is electrically connected to the first driving lines, and is configured to transmit a high voltage-level signal to the first driving lines. The second driving module is electrically connected to the second driving lines, and is configured to transmit a low voltage-level signal to the second driving lines. The sensing module is electrically connected to the second driving module, includes a plurality of sensing pins that are electrically connected respectively to the sensing lines, and is configured to measure an analog value of voltage at each of the sensing pins.

### BRIEF DESCRIPTION OF THE DRAWINGS

Other features and advantages of the disclosure will become apparent in the following detailed description of the embodiment(s) with reference to the accompanying drawings. It is noted that various features may not be drawn to scale.

FIG. 1 is a schematic diagram of a keyboard circuit of a light-emitting anti-ghosting keyboard according to an embodiment of the present disclosure.

FIGS. 2 to 4 are schematic diagrams each illustrating a current flow through a different switch module of the keyboard circuit according to an embodiment of the present disclosure.

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

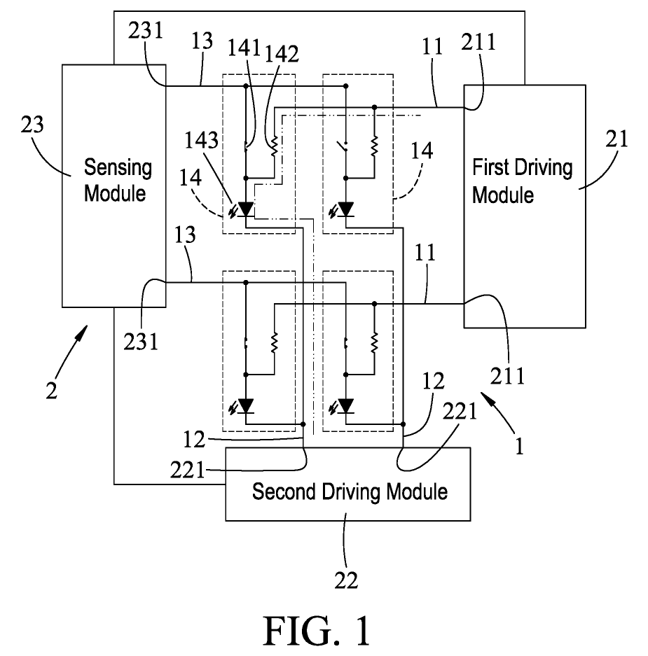

Referring to FIG. 1, a keyboard circuit of a light-emitting anti-ghosting keyboard according to an embodiment of the disclosure includes a switch unit 1 and a processing unit 2.

The switch unit 1 includes a plurality of first driving lines 11, a plurality of second driving lines 12, a plurality of sensing lines 13, and a plurality of switch modules 14. For illustration purposes, each of a number of the first driving lines 11, a number of the second driving lines 12, and a number of the sensing lines 13 is taken as two for example, and a number of the switch modules 14 is taken as four for example. However, in other embodiments, the number of the first driving lines 11, the number of the second driving lines 12, the number of the sensing lines 13, and the number of the switch modules 14 may be adjusted according to requirements.

Each of the switch modules 14 is electrically connected to one of the first driving lines 11, one of the second driving lines 12, and one of the sensing lines 13. Each of the switch modules 14 includes a switch 141, a current-limiting resistor 142, and a light-emitting diode (LED) 143. The switch 141 has a first end and a second end. The first end of the switch 141 is electrically connected to the corresponding one of the sensing lines 13. The current-limiting resistor 142 has a first end electrically connected to the second end of the switch 141, and a second end electrically connected to the corresponding one of the first driving lines 11. The LED 143 has an anode electrically connected to the second end of the switch 141 and the first end of the current-limiting resistor 142, and a cathode electrically connected to the corresponding one of the second driving lines 12. The LED 143 is configured to emit light based on an operation of the processing unit 2. That is to say, when the processing unit 2 causes the LED 143 to be in a state of forward bias (i.e., a voltage at the anode of the LED 143 is greater than a voltage at the cathode of the LED 143 by a forward threshold voltage), the LED 143 emits light. Details of the operation of the processing unit 2 causing the LED 143 to emit light will be provided in the following.

The processing unit 2 includes a first driving module 21 electrically connected to the first driving lines 11, a second driving module 22 electrically connected to the second driving lines 12, and a sensing module 23 electrically connected to the second driving module 22 and the sensing lines 13. In one embodiment, the processing unit 2 is implemented by an integrated circuit (e.g., IT8258E manufactured by ITE Tech. Inc.) including a processor (e.g., a microprocessor) and a computer readable storage medium (e.g., an erasable programmable read-only memory (EPROM)). The computer readable storage medium is electrically connected to the processor and stores instructions that, when executed by the processor, causes the processor to execute the operations as described below. However, the processing unit 2 is not limited in this respect.

The first driving module 21 is configured to transmit a high voltage-level signal to the first driving lines 11. In some embodiments, the first driving module 21 includes a plurality of first driving pins 211 electrically connected respectively to the first driving lines 11, and the first driving module 21 is configured to transmit the high voltage-level signal to the first driving lines 11 in sequence respectively through the first driving pins 211. In some embodiments, a voltage value of the high voltage-level signal is within a range of 3 V to 5.25 V. It should be noted that, the voltage value of the high voltage-level signal corresponds to the type of the LED 143, and a resistance value of the current-limiting resistor 142 corresponds to the type of the LED 143. For example, for each of the switch modules 14, when the LED 143 is a red LED that emits red light, where a forward threshold voltage of the red LED is usually within a range of 1.5 V to 2.5 V (e.g., 1.8 V), the voltage value of the high voltage-level signal may be set to 3 V and a resistor with a resistance value of 120 Ω may be used as the current-limiting resistor 142 for driving the red LED to emit light. When the LED 143 is a blue LED that emits blue light, where a forward threshold voltage of the blue LED is usually within a range of 2.5 V to 3.5 V (e.g., 3.3 V), the voltage value of the high voltage-level signal may be set to 5 V and a resistor with a resistance value of 170 Ω may be used as the current-limiting resistor 142 for driving the blue LED to emit light. When the LED 143 is a white LED that emits white light, where a forward threshold voltage of the white LED is usually within a range of 2.75 V to 3.75 V (e.g., 3.6 V), the voltage value of the high voltage-level signal may be set to 5 V and a resistor with a resistance value of 140 Ω may be used as the current-limiting resistor 142 for driving the white LED to emit light. For each of the switch modules 14, by virtue of setting the voltage value of the high voltage-level signal and determining the resistance value of the current-limiting resistor 142 to be used according to the type the LED 143, a current flowing through the current-limiting resistor 142 may be controlled (e.g., the current to be substantially close to 0.01 A), thereby reducing a power consumption caused by the current-limiting resistor 142.

The second driving module 22 is configured to transmit a low voltage-level signal to the second driving lines 12. In some embodiments, the second driving module 22 includes a plurality of second driving pins 221 electrically connected respectively to the second driving lines 12, and the second driving module 22 is configured to transmit the low voltage-level signal to the second driving lines 12 in sequence respectively through the second driving pins 221 each time the first driving module 21 transmits the high voltage-level signal to one of the first driving lines 11. In some embodiments, a voltage value of the low voltage-level signal is within a range of -0.1 V to 0.1 V, making the second driving module 22 substantially equivalent to a ground terminal.

The sensing module 23 includes a plurality of sensing pins 231 that are electrically connected respectively to the sensing lines 13, and is configured to measure an analog value of the voltage at each of the sensing pins 231. In one embodiment, the sensing module 23 stores a predetermined voltage value of the forward threshold voltage of the LEDs 143 respectively of the switch modules 14, where the predetermined voltage value of the forward threshold voltage of each LED 143 corresponds to the type of the LED 143 (e.g., 1.8 V for the red LED, 3.3 V for the blue LED, and 3.6 V for the white LED). In this embodiment, the LEDs 143 respectively of the switch modules 14 are of the same type. In other embodiments, the LEDs 143 may be of different types, and thus the sensing module 23 may store a plurality of predetermined voltage values corresponding respectively to the LEDs 143. The sensing module 23 is further configured to, for each of the switch modules 14, determine whether the switch 141 is depressed by comparing a predetermined threshold to the analog value of the voltage at one of the sensing pins 231 that is electrically connected to the switch 141. The predetermined threshold is related to the predetermined voltage value and the voltage value of the high voltage-level signal. In some embodiments, the sensing module 23 is further electrically connected to the first driving module 21, and is further configured to receive the high voltage-level signal from the first driving module 21 so as to obtain the voltage value of the high voltage-level signal, and to calculate an average of the predetermined voltage value and the voltage value of the high voltage-level signal as the predetermined threshold. In other embodiments, the sensing module 23 further stores the voltage value of the high voltage-level signal, and the electrical connection between the sensing module 23 and the first driving module 21 may be omitted in such embodiments.

Referring to FIGS. 1 to 4, an example where three switches 141 respectively of a top left, a bottom left, and a bottom right ones of the switch modules 14 are simultaneously depressed is shown. In this example, the first driving module 21 transmits the high voltage-level signal to the first driving lines 11 in sequence respectively through the first driving pins 211, and the second driving module 22 transmits the low voltage-level signal to the second driving lines 12 in sequence respectively through the second driving pins 221 each time the first driving module 21 transmits the high voltage-level signal to one of the first driving lines 11. Specifically, in this example, the switch modules 14 are sequentially in a sensing state to receive both the high voltage-level signal and the low voltage-level signal in the following order: the top left one of the switch modules 14 (hereinafter referred to as “the first switch module 14”), a top right one of the switch modules 14 (hereinafter referred to as “the second switch module 14”), the bottom left one of the switch modules 14 (hereinafter referred to as “the third switch module 14”), and the bottom right one of the switch modules 14 (hereinafter referred to as “the fourth switch module 14”). Each time when one of the switch modules 14 receives both the high voltage-level signal and the low voltage-level signal, the sensing module 23 measures the analog value of the voltage at the corresponding one of the sensing pins 231 that is connected to the switch 141 of said one of the switch modules 14.

Referring to FIG. 1, the first switch module 14 is the first to receive both the high voltage-level signal and the low voltage-level signal. Specifically, the first driving module 21 transmits the high voltage-level signal to the top first driving line (i.e., the top one of the first driving lines 11) through the top first driving pin (i.e., the top one of the first driving pins 211), and the second driving module 22 transmits the low voltage-level signal to the left second driving line (i.e., the left one of the second driving lines 12) through the left second driving pin (i.e., the left one of the second driving pins 221), thereby causing the LED 143 of the first switch module 14 (hereinafter referred to as “the first LED 143) to be in the state of forward bias which enables current to flow through the first LED 143 (as depicted by the dot-dot-dashed line in FIG. 1), and to emit light. At this moment, the switch 141 of the first switch module 14 is depressed and is in a conducting state. The sensing module 23 measures the analog value of the voltage at the top sensing pin (i.e., the top one of the sensing pins 231), and the analog value of the voltage thus measured is equivalent to the forward threshold voltage of the first LED 143 (i.e., a minimum voltage required to cause the first LED 143 to be in the state of forward bias). Since the forward threshold voltage of the first LED 143 corresponds to the type of the first LED 143, the analog value of the voltage that is measured at the top sensing pin 231 at this moment when the first LED 143 is in the state of forward bias depends on the type of the first LED 143. In this example, the analog value of the voltage that is measured when the first LED 143 is in the state of forward bias is greater than 1.5 V and is smaller than the voltage value of the high voltage-level signal. The sensing module 23 obtains the predetermined threshold by calculating an average of the predetermined voltage value corresponding to the first LED 143 and the voltage value of the high voltage-level signal, and compares the predetermined threshold to the analog value of the voltage thus measured. In some embodiments, the sensing module 23 is configured to pre-store the predetermined threshold. When the analog value of the voltage thus measured is smaller than the predetermined threshold, which means that the analog value of the voltage thus measured is closer to the predetermined threshold as compared to the voltage value of the high voltage-level signal, the sensing module 23 determines that the switch 141 of the first switch module 14 is depressed.

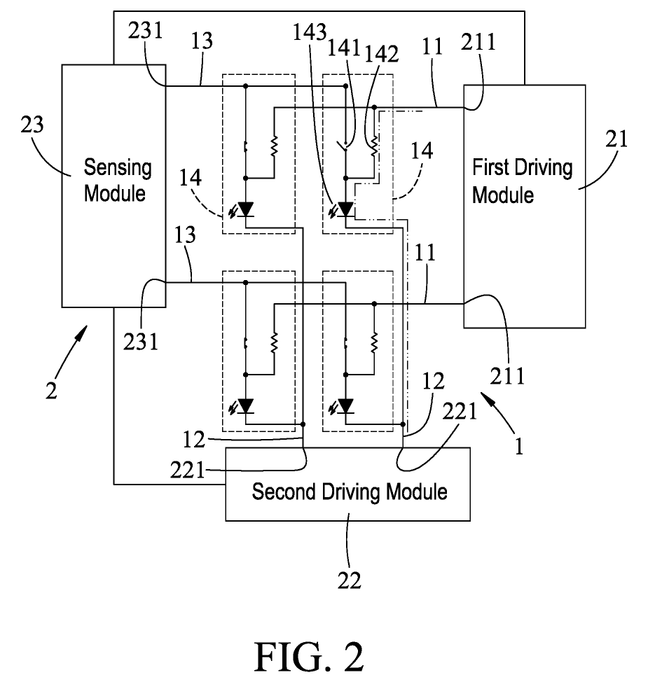

Referring to FIG. 2, the second switch module 14 is the second to receive both the high voltage-level signal and the low voltage-level signal. Specifically, the first driving module 21 transmits the high voltage-level signal to the top first driving line 11 through the top first driving pin 211, and the second driving module 22 transmits the low voltage-level signal to the right second driving line (i.e., the right one of the second driving lines 12) through the right second driving pin (i.e., the right one of the second driving pins 221), thereby causing the LED 143 of the second switch module 14 (hereinafter referred to as “the second LED 143”) to be in the state of forward bias which enables current to flow through the second LED 143 (as depicted by the dot-dot-dashed line in FIG. 2), and to emit light. At this moment, the switch 141 of the second switch module 14 is not depressed and is in a non-conducting state. When the sensing module 23 measures the analog value of the voltage at the top sensing pin 231, since the switch 141 of the second switch module 14 is in the non-conducting state, the analog value of the voltage thus measured corresponds to the high voltage-level signal outputted by the top first driving pin 211, and thus is equivalent to the voltage value of the high voltage-level signal. The sensing module 23 obtains the predetermined threshold by calculating an average of the predetermined voltage value corresponding to the second LED 143 and the voltage value of the high voltage-level signal, and compares the predetermined threshold to the analog value of the voltage thus measured at this moment. When the analog value of the voltage thus measured is greater than the predetermined threshold, which means that the analog value of the voltage thus measured is closer to the high voltage-level signal as compared to the predetermined threshold, the sensing module 23 determines that the switch 141 of the second switch module 14 is not depressed.

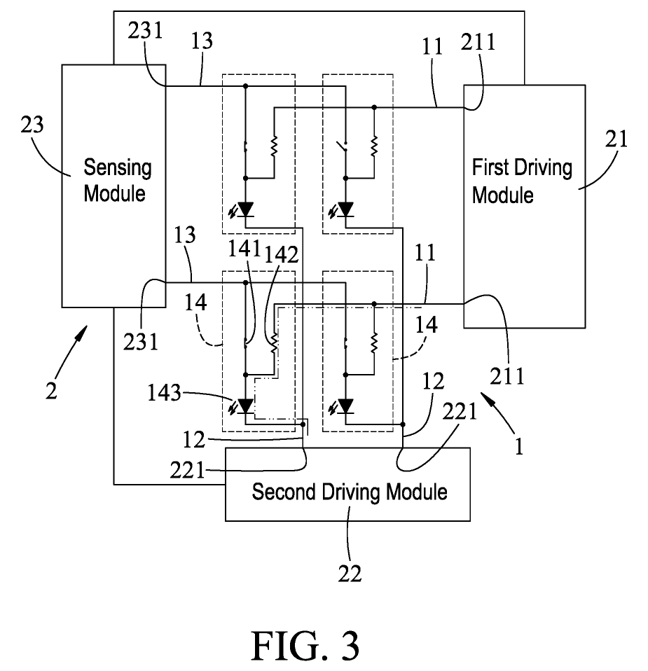

Referring to FIG. 3, the third switch module 14 is the third to receive both the high voltage-level signal and the low voltage-level signal. Specifically, the first driving module 21 transmits the high voltage-level signal to the bottom first driving line (i.e., the bottom of the first driving lines 11) through the bottom first driving pin (i.e., the bottom one of the first driving pins 211), and the second driving module 22 transmits the low voltage-level signal to the left second driving line 12 through the left second driving pin 221, thereby causing the LED 143 of the third switch module 14 (hereinafter referred to as “the third LED 143”) to be in the state of forward bias which enables current to flow through the third LED 143 (as depicted by the dot-dot-dashed line in FIG. 3), and to emit light. At this moment, the switch 141 of the third switch module 14 is depressed and is in the conducting state. The sensing module 23 measures the analog value of the voltage at the bottom sensing pin (i.e., the bottom one of the sensing pins 231), and the analog value of the voltage measured at this moment is equivalent to the forward threshold voltage of the third LED 143 (i.e., a minimum voltage required to cause the third LED 143 to be in the state of forward bias). Since the forward threshold voltage of the third LED 143 corresponds to the type of the third LED 143, the analog value of the voltage that is measured at the bottom sensing pin 213 at this moment when the third LED 143 is in the state of forward bias depends on the type of the third LED 143. In this example, the analog value of the voltage that is measured when the third LED 143 is in the state of forward bias is greater than 1.5 V and is smaller than the voltage value of the high voltage-level signal. The sensing module 23 obtains the predetermined threshold by calculating an average of the predetermined voltage value corresponding to the third LED 143 and the voltage value of the high voltage-level signal, and compares the predetermined threshold to the analog value of the voltage thus measured. When the analog value of the voltage thus measured is smaller than the predetermined threshold, which means that the analog value of the voltage thus measured is closer to the predetermined threshold as compared to the voltage value of the high voltage-level signal, the sensing module 23 determines that the switch 141 of the third switch module 14 is depressed.

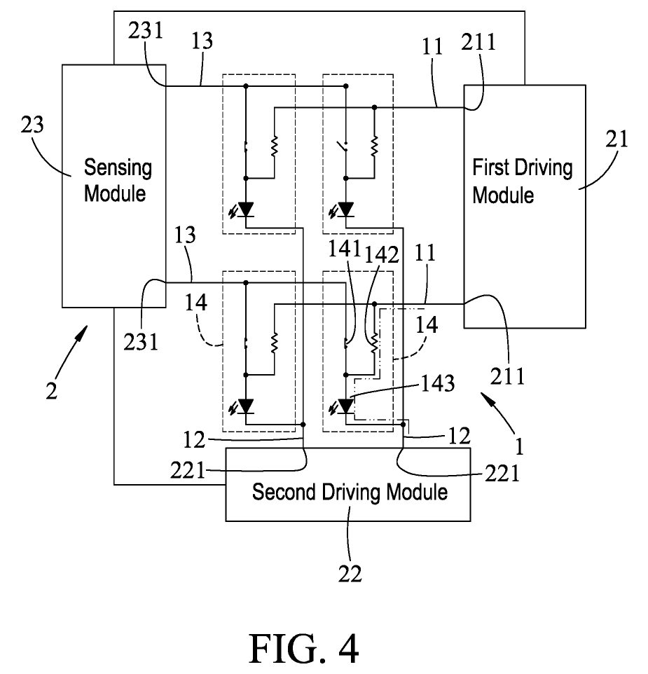

Referring to FIG. 4, the fourth switch module 14 is the last to receive both the high voltage-level signal and the low voltage-level signal. Specifically, the first driving module 21 transmits the high voltage-level signal to the bottom first driving line 11 through the bottom first driving pin 211, and the second driving module 22 transmits the low voltage-level signal to the right second driving line 12 through the right second driving pin 221, thereby causing the LED 143 of the fourth switch module 14 (hereinafter referred to as “the fourth LED 143”) to be in the state of forward bias which enables current to flow through the fourth LED 143 (as depicted by the dot-dot-dashed line in FIG. 4), and to emit light. At this moment, the switch 141 of the fourth switch module 14 is depressed and is in the conducting state. The sensing module 23 measures the analog value of the voltage at the bottom sensing pin 231, and the analog value of the voltage measured at this moment is equivalent to the forward threshold voltage of the fourth LED 143 (i.e., a minimum voltage required to cause the fourth LED 143 to be in the state of forward bias). Since the forward threshold voltage of the fourth LED 143 corresponds to the type of the fourth LED 143, the analog value of the voltage that is measured at the bottom sensing pin 231 at this moment when the fourth LED 143 is in the state of forward bias depends on the type of the fourth LED 143. In this example, the analog value of the voltage that is measured when the fourth LED 143 is in the state of forward bias is greater than 1.5 V and is smaller than the voltage value of the high voltage-level signal. The sensing module 23 obtains the predetermined threshold by calculating an average of the predetermined voltage value corresponding to the fourth LED 143 and the voltage value of the high voltage-level signal, and compares the predetermined threshold to the analog value of the voltage thus measured. When the analog value of the voltage thus measured is smaller than the predetermined threshold, which means that the analog value of the voltage thus measured is closer to the predetermined threshold as compared to the voltage value of the high voltage-level signal, the sensing module 23 determines that the switch 141 of the fourth switch module 14 is depressed.

U.S. patent application No. 18/767114 discloses a conventional anti-ghosting keyboard that includes a sensing unit, a detection unit and a processing module. The sensing unit includes a plurality of sensor modules. Each of the sensor modules includes N number of switch elements, and N number of sensing resistors that correspond respectively to the switch elements, where N is a positive integer greater than one. For each of the sensor modules, resistance values respectively of the N number of sensing resistors form an ascending sequence, and any one of the resistance values in the ascending sequence, except for a first one of the resistance values, is greater than a sum of all of those of the resistance values before itself (i.e., said any one of the resistance values) in the ascending sequence. A conduction status of the N number of switch elements causes the sensor module to produce an equivalent resistance value, which is one of 2^{N} number of possible equivalent resistance values that respectively correspond to 2^{N} number of possible conduction statuses of the N number of switch elements. The detection unit obtains a divided voltage value that corresponds to the equivalent resistance value, and generates a potential level value based on the divided voltage value. The processing module then determines the conduction status of the switch elements based on the potential level value. By virtue of the arrangements of this conventional anti-ghosting keyboard (U.S. patent application No. 18/767114), the conventional anti-ghosting keyboard is able to determine which of the switch elements is/are activated, and the generation of “ghost keys” can be prevented. Using the concept of obtaining the divided voltage value from U.S. patent application No. 18/767114, and combining the concept with physical properties of an LED, the keyboard circuit of this disclosure is able to prevent the generation of “ghost keys” and to emit light.

In summary, the first driving module 21 transmits the high voltage-level signal to the first driving lines 11 in sequence respectively through the first driving pins 211, and the second driving module 22 transmits the low voltage-level signal to the second driving lines 12 in sequence respectively through the second driving pins 221 each time the first driving module 21 transmits the high voltage-level signal to one of the first driving lines 11. By virtue of reverse cutoff characteristics of the LEDs 143 respectively of the switch modules 14, when the switch modules 14 sequentially receive the high voltage-level signal and the low voltage-level signal, the sensing module 23 is able to measure the analog value of the voltage at a corresponding one of the sensing pins 231, and is able to determine, for each of the switch modules 14, whether the switch 141 is depressed, thereby achieving anti-ghosting.

In addition, the first driving module 21, the second driving module 22, the current-limiting resistors 142 respectively of the switch modules 14, and the LEDs 143 of the switch modules 14 cooperatively enables the keyboard circuit of this disclosure to emit light. By virtue of adjusting the voltage value of the high voltage-level signal and the resistance value of the current-limiting resistors 142, high power consumption caused by the current-limiting resistors 142 may be reduced.

Therefore, the keyboard circuit of this disclosure is able to achieve anti-ghosting and to emit light.

In the description above, for the purposes of explanation, numerous specific details have been set forth in order to provide a thorough understanding of the embodiment(s). It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects; such does not mean that every one of these features needs to be practiced with the presence of all the other features. In other words, in any described embodiment, when implementation of one or more features or specific details does not affect implementation of another one or more features or specific details, said one or more features may be singled out and practiced alone without said another one or more features or specific details. It should be further noted that one or more features or specific details from one embodiment may be practiced together with one or more features or specific details from another embodiment, where appropriate, in the practice of the disclosure.

While the disclosure has been described in connection with what is(are) considered the exemplary embodiment(s), it is understood that this disclosure is not limited to the disclosed embodiment(s) but is intended to cover various arrangements included within the spirit and scope of the broadest interpretation so as to encompass all such modifications and equivalent arrangements.

What is claimed is:

1. A keyboard circuit of a light-emitting anti-ghosting keyboard, comprising:
a switch unit including a plurality of first driving lines, a plurality of second driving lines, a plurality of sensing lines, and a plurality of switch modules, each of said plurality of switch modules electrically connected to one of said plurality of first driving lines, one of said plurality of second driving lines, and one of said plurality of sensing lines, and including
a switch having a first end and a second end, said first end of said switch electrically connected to said one of said plurality of sensing lines,
a current-limiting resistor having a first end electrically connected to said second end of said switch, and a second end electrically connected to said one of said plurality of first driving lines, and
a light-emitting diode (LED) having an anode electrically connected to said second end of said switch and said first end of said current-limiting resistor, and a cathode electrically connected to said one of said plurality of second driving lines; and
a processing unit including
a first driving module electrically connected to said plurality of first driving lines, and configured to transmit a high voltage-level signal to said plurality of first driving lines,
a second driving module electrically connected to said plurality of second driving lines, and configured to transmit a low voltage-level signal to said plurality of second driving lines, and
a sensing module electrically connected to said second driving module, including a plurality of sensing pins that are electrically connected respectively to said plurality of sensing lines, and configured to measure an analog value of voltage at each of said plurality of sensing pins.

2. The keyboard circuit as claimed in claim 1, wherein said first driving module includes a plurality of first driving pins electrically connected respectively to said plurality of first driving lines, and said second driving module includes a plurality of second driving pins electrically connected respectively to said plurality of second driving lines.

3. The keyboard circuit as claimed in claim 2, wherein said first driving module is configured to transmit the high voltage-level signal to said plurality of first driving lines in sequence respectively through said plurality of first driving pins,
wherein said second driving module is configured to transmit the low voltage-level signal to said plurality of second driving lines in sequence respectively through said plurality of second driving pins each time said first driving module transmits the high voltage-level signal to one of said plurality of first driving lines.

4. The keyboard circuit as claimed in claim 3, wherein said sensing module stores a predetermined voltage value of forward threshold voltage of said LED,
wherein said sensing module is further configured to, for each of said plurality of switch modules, determine whether said switch is depressed by comparing a predetermined threshold to the analog value of voltage at one of said plurality of sensing pins that is electrically connected to one of said plurality of sensing lines electrically connected to said switch, the predetermined threshold being related to the predetermined voltage value and a voltage value of the high voltage-level signal.

5. The keyboard circuit as claimed in claim 4, wherein said sensing module is electrically connected to said first driving module, and is configured to receive the high voltage-level signal from said first driving module so as to obtain the voltage value of the high voltage-level signal, and to calculate an average of the predetermined voltage value and the voltage value of the high voltage-level signal as the predetermined threshold.

6. The keyboard circuit as claimed in claim 4, wherein the predetermined voltage value of the forward threshold voltage of said LED corresponds to a type of said LED.

7. The keyboard circuit as claimed in claim 1, wherein a resistance value of said current-limiting resistor corresponds to a type of said LED.

8. The keyboard circuit as claimed in claim 1, wherein a voltage value of the high voltage-level signal corresponds to a type of said LED.

9. The keyboard circuit as claimed in claim 1, wherein a voltage value of the high voltage-level signal is within a range of 3 V to 5.25 V, and a voltage value of the low voltage-level signal is within a range of -0.1 V to 0.1 V.
